(19) United States
(12) Patent Application Publication
(10) Pub. No.: US 2012/0098099 A1
(43) Pub. Date: Apr. 26, 2012

(54) SEMICONDUCTOR DEVICE AND METHOD OF MANUFACTURING THE SAME

(75) Inventors: Jongmin LEE, Daejeon (KR); Byoung-Gue Min, Daejeon (KR); Seong-il Kim, Daejeon (KR); Hyung Sup Yoon, Daejeon (KR); Hae Cheon Kim, Daejeon (KR); Eun Soo Nam, Daejeon (KR)

(73) Assignee: ELECTRONICS AND TELECOMMUNICATIONS RESEARCH INSTITUTE, Daejeon (KR)

(21) Appl. No.: 13/193,670

(22) Filed: Jul. 29, 2011

(30) Foreign Application Priority Data
Oct. 26, 2010 (KR) 10-2010-0104620

(51) Int. Cl. H01L 27/06; H01L 21/8222

(52) U.S. Cl. 257/577; 438/328; 257/E27.011; 257/E21.608

(57) ABSTRACT

Provided are a compound semiconductor device and a method of manufacturing the same. The semiconductor device includes: a substrate including a first region and a second region; a transistor including first to third conductive impurity layers stacked on the substrate of the first region; and a variable capacitance diode spaced apart from the transistor of the first region and including the first and second conductive impurity layers stacked on the substrate of the second region.

### CROSS-REFERENCE TO RELATED APPLICATIONS

This U.S. non-provisional patent application claims priority under 35 U.S.C. §119 of Korean Patent Application No. 10-2010-0104620, filed on Oct. 26, 2010, the entire contents of which are hereby incorporated by reference.

### BACKGROUND OF THE INVENTION

The present invention disclosed herein relates to a semiconductor device and a method of manufacturing the same, and more particularly, to a compound semiconductor device and a method of manufacturing the same.

Recently, as wireless communication technologies have been developed in diverse forms, technical limitations for supporting different wireless communication standards arise. In order to resolve above limitations, portable terminals having integrated high performance techniques such as multi-band, a multi-mode, and a multi-function are required. The portable terminals may include a semiconductor device into which a power amplifier is essentially built. The portable terminals may satisfy different communication systems when the number of frequencies in use is increased or frequencies in use are variable. However, a typical semiconductor device needs to carry the corresponding number of amplifiers each time frequencies in use are changed or the number of frequencies in use is increased. As a result, a chip size is increased.

### SUMMARY OF THE INVENTION

The present invention provides a semiconductor device minimizing a chip size and a method of manufacturing the same.

The present invention also provides a thin film depositing apparatus to increase or maximize productivity.

Embodiments of the present invention provide semiconductor devices including: a substrate including a first region and a second region; a transistor including first to third conductive impurity layers stacked on the substrate of the first region; and a variable capacitance diode spaced apart from the transistor of the first region and including the first and second conductive impurity layers stacked on the substrate of the second region.

In some embodiments, the first to third conductive impurity layers may include a collector layer, a base layer, and an emitter layer, respectively.

In other embodiments, the variable capacitance diode may include a sub collector layer between the first conductive impurity layer and the substrate.

In still other embodiments, the transistor may include a first electrode on the emitter layer, a second electrode on the base layer, and a third electrode on the sub collector layer; and the variable capacitance capacitor may include a fourth electrode on the base layer and a plurality of fifth electrodes on the sub collector layer.

In even other embodiments, the semiconductor devices may further comprising a fixed capacitance capacitor having: a lower electrode extending from at least one of the plurality of fifth electrodes on the substrate in the second region and around a boundary of the second region; an insulation layer on the lower electrode; and an upper electrode on the insulation layer facing the lower electrode.

In other embodiments of the present invention, methods of manufacturing a semiconductor device include: stacking first to third conductive impurity layers on a front of a substrate including first and second regions; exposing the second conductive impurity layer by removing the third conductive impurity layer on the first region and partially removing the third conductive impurity layer on the second region; and forming a transistor including the first to third conductive impurity layers on the first region and a variable capacitance diode including the first and second conductive impurity layers on the second region by partially removing the second and third conductive impurity layers on the first and second regions, respectively.

In some embodiments, the methods may further include forming a sub conductive impurity layer having the same conductive type as the first conductive impurity layer between the first conductive impurity layer and the substrate.

In other embodiments, the sub conductive impurity layer may be exposed when the second and third conductive impurities are removed.

In still other embodiments, the methods may further include separating the variable capacitance diode from the transistor by removing a portion of the substrate between the first and second regions and the sub conductive impurity.

In even other embodiments, the methods may further include forming first to third contact pads on the first to third conductive impurity layers in the first and second regions.

In yet other embodiments, the methods may further include: forming a first insulation layer on a front of the substrate including the first to third contact pads; and forming first contact holes by partially removing the first insulation layer on the first and third contact pads.

In further embodiments, the methods may further include forming first to third electrodes connected to the first to third contact pads in the first contact holes.

In still further embodiments, at least one of the third electrodes on the second region comprises a lower electrode extended between the first region and the second region.

In even further embodiments, the methods may further include: forming a second insulation layer on the front of the substrate on the lower electrode; and forming an upper electrode on the second insulation layer facing the lower electrode.

In yet further embodiments, the methods may further include: forming a third insulation layer on the front of the substrate including the upper electrode; forming second contact holes by removing the second insulation layer and the third insulation layer on the first to third electrodes and the third insulation layer on the upper electrode; and forming first to fourth interconnections connected to the first to third electrodes and the upper electrode in the second contact holes.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIGS. 1A and 1B are sectional views illustrating a semiconductor device according to an embodiment of the present invention;

FIG. 2 is a circuit diagram illustrating a connection relationship between a bipolar transistor, a fixed capacitance capacitor, and variable capacitance diodes of FIGS. 1A and 1B; and

FIGS. 3A through 3K are sectional views illustrating a method of manufacturing a semiconductor device according to an embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout.

The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components. Since preferred embodiments are provided below, the order of the reference numerals given in the description is not limited thereto.

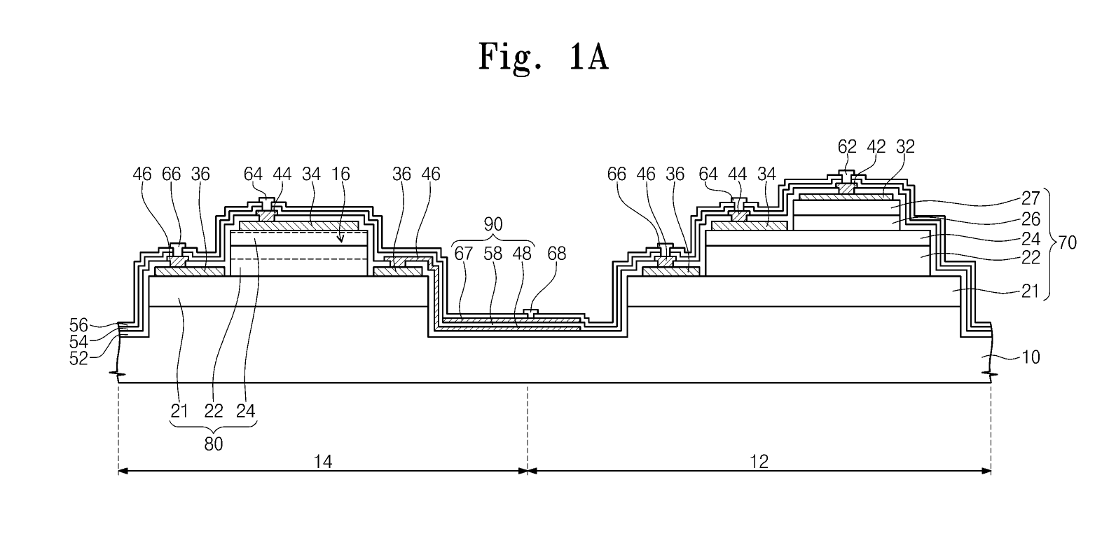

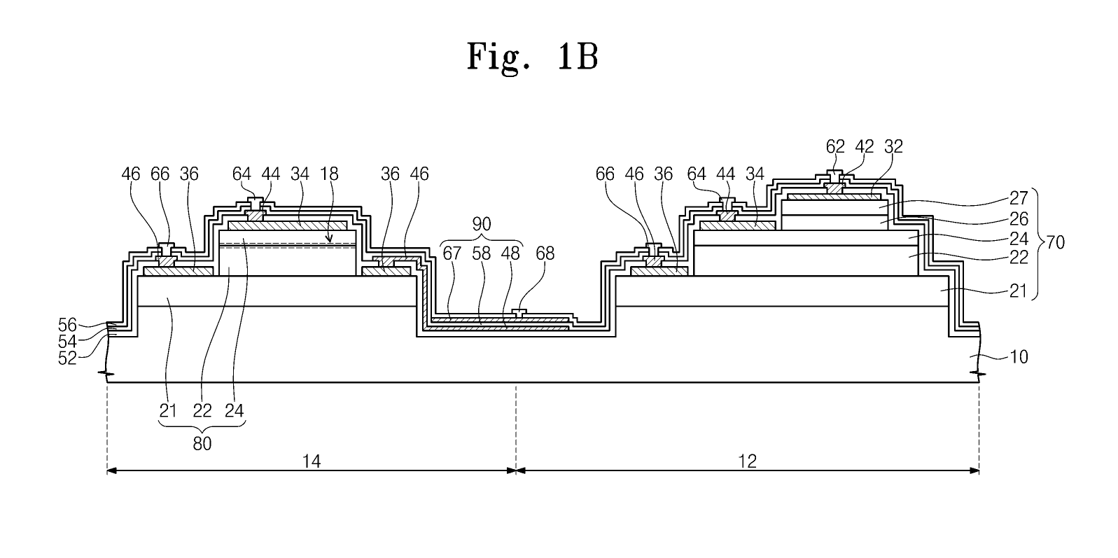

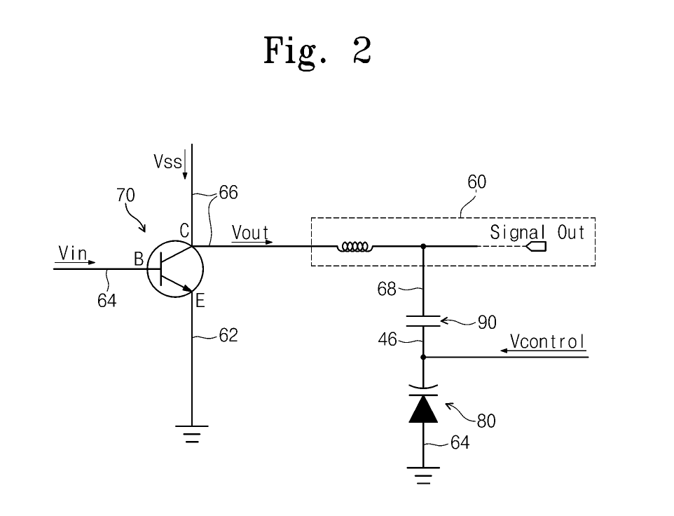

FIGS. 1A and 1B are sectional views illustrating a semiconductor device according to an embodiment of the present invention. FIG. 2 is a circuit diagram illustrating a connection relationship between a bipolar transistor, a fixed capacitance capacitor, and variable capacitance diodes of FIGS. 1A and 1B.

Referring to FIGS. 1A and 2, the semiconductor device may include a bipolar transistor 70 and a variable capacitance diode 80, which are spaced from each other in respective first and second regions 12 and 14 on a substrate 10. The bipolar transistor 70 may be an amplifier that may amplify an input voltage Vᵢₙ up to more than a predetermined level. An input impedance of the bipolar transistor 70 may be changed according to a frequency of the input voltage Vᵢₙ. An output impedance of the bipolar transistor 70 may be determined by a resistance value of an output unit 60 and capacitance values of the variable capacitance diode 80 and the fixed capacitance capacitor 90. The output unit 60 may output an output voltage Vₒᵤₜ at the maximum when input and output impedances are matched. The variable capacitance diode 80 may change an output impedance through a control voltage V_{control}. The variable capacitance diode 80 may match an output impedance with that of the bipolar transistor 70 even if a frequency of the input voltage Vᵢₙ is changed.

Accordingly, since the semiconductor device may minimize a chip size, productivity may be increased or maximized.

The bipolar transistor 70 may include a collector layer 22, a base layer 24, and an emitter layer 26, on the substrate 10. The collector layer 22, the base layer 24, and the emitter layer 26 may include first to third conductive impurity layers where first and second conductive impurities are alternately disposed. For example, the collector layer 22 and the emitter layer 26 may include a compound semiconductor such as GaAs doped with an n-type conductive impurity (i.e., a dopant). The base layer 24 may include a compound semiconductor doped with a p-type conductive impurity. The collector layer 22, the base layer 24, and the emitter layer 26 may have an npn or pnp layer stacked structure.

The variable capacitance diode 80 may include the collector layer 22 and the base layer 24. The variable capacitance diode 80 may include first and second depletion regions 16 and 18 induced between the collector layer 22 and the base layer 24 according to the control voltage V_{control}. The first depletion region 16 may be induced when reverse bias is applied to between the collector layer 22 and the base layer 24. The second depletion region 18 may be induced when forward bias is applied to between the collector layer 22 and the base layer 24.

In relation to the variable capacitance diode 80, its capacitance value may be reduced when the first depletion region 16 is induced between the collector layer 22 and the base layer 24. In relation to the variable capacitance diode 80, its capacitance value may be increased when the second depletion region 18 is induced between the collector layer 22 and the base layer 24. The capacitance value is inversely proportional to the distance of the first and second depletion regions 16 and 18.

A sub collector layer 21 may be disposed below the collector layer 22. An emitter cap layer 27 may be disposed on the emitter layer 26. The sub collector 21 and the emitter cap layer 27 may be doped with the same conductive impurity as the collector layer 22 and the emitter layer 26, respectively. The sub collector layer 21 and the emitter layer 26 may be doped with an n-type or p-type conductive impurity of a higher concentration than the collector layer 22 and the emitter layer 26. First contact pads 32 and first electrodes 42 may be disposed on the emitter cap layer 27. The base layer 27 and the collector layer 22 may include a pn or np junction. Second contact pads 34 and second electrodes 44 may be disposed on the base layer 24. Third contact pads 36 and third electrodes 46 may be disposed on the sub collector layer 21.

The variable capacitance diode 80 may include the plurality of third contact pads 36 and third electrodes 46 on the sub collector layer 21. At least one of the third electrodes 46 of the variable capacitance diode 80 may be connected to the lower electrode 48 of the fixed capacitor 90.

The fixed capacitance capacitor 90 may be disposed between the first and second regions 12 and 14. The fixed capacitance capacitor 90 may be disposed between the bipolar transistor 70 and the variable capacitance diode 80. The fixed capacitance capacitor 90 may include a lower electrode 48, a dielectric layer 58, and an upper electrode 67. The lower electrode 48 and the upper electrode 67 may include at least one of metals such as gold, silver, copper, tungsten, aluminum, or molybdenum. Accordingly, the fixed capacitance capacitor 90 may include a metallic layer, an insulation layer, and a metallic layer of Metal Insulator Metal (MIM).

The first insulation layer 52 may be disposed on the first to third contact pads 32, 34, and 36. The second insulation layer 54 and the third insulation layer 56 may be disposed on the first to third electrodes 42, 44, and 46. The upper electrode 67 may be disposed between the second insulation layer 54 and the third insulation layer 56. First to fourth interconnections 62, 64, 66, and 68 may be disposed on the first to third electrodes 42, 44, and 46 and the upper electrode 67. The first to fourth interconnections 62, 64, 66, and 68 may be disposed on the third insulation layer 56.

The first interconnection 62 of the bipolar transistor 70 may be grounded. An input voltage Vin may be applied to the base layer 24 of the bipolar transistor 70 through the second interconnection 64. A collector voltage Vcc may be applied to the collector layer 22 of the bipolar transistor 70. The collector layer 22 of the bipolar transistor 70 may be connected to the output unit 60 through the third interconnection 66.

The base layer 24 of the variable capacitance diode 80 may be grounded through the second interconnection 64. The sub collector layer 21 and the collector layer 22 of the variable capacitance diode 80 may be connected to the lower electrode 48 of the fixed capacitance capacitor 90 through the third electrode 46. The control voltage V_{control} may be applied to the third electrode 46 or the third interconnection 66 of the variable capacitance diode 80. The upper electrode 67 of the fixed capacitance capacitor 90 may be connected to the output unit 60 through the fourth interconnection 68. The bipolar transistor 70 and the variable capacitance diode 80 may be integrated on one substrate 10. Accordingly, a chip size of a semiconductor device according to an embodiment of the present invention may be minimized

A method of manufacturing a semiconductor device according to an embodiment of the present invention will be described.

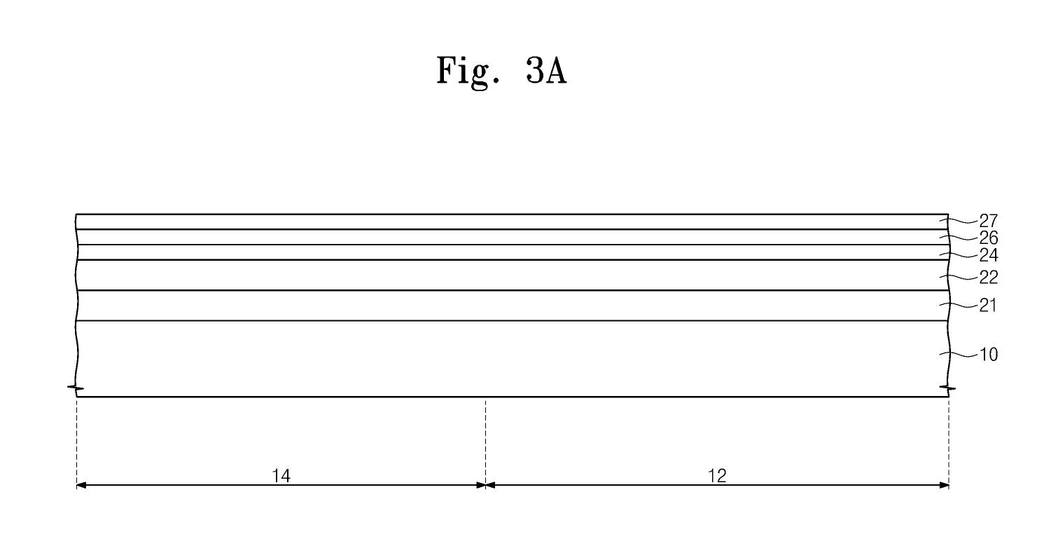

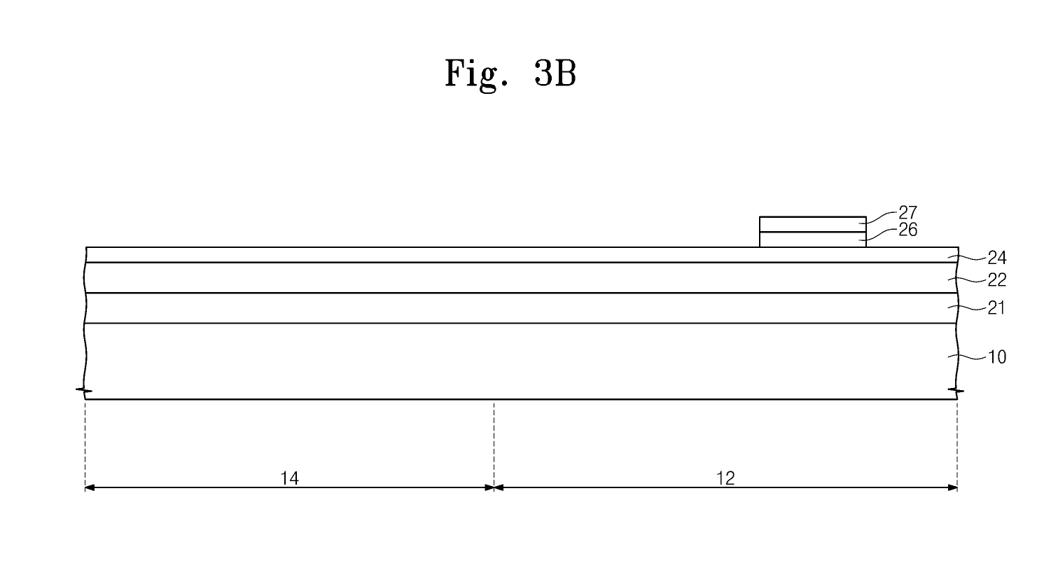

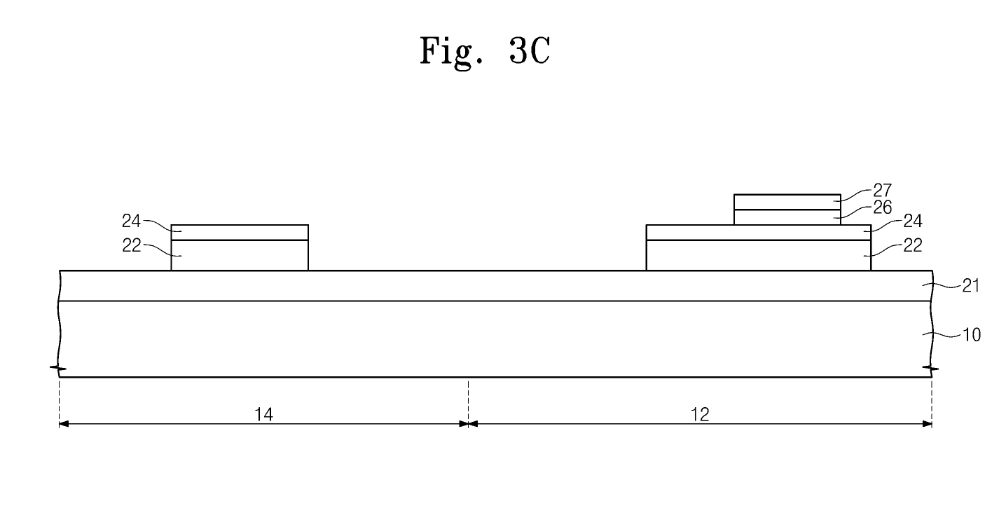

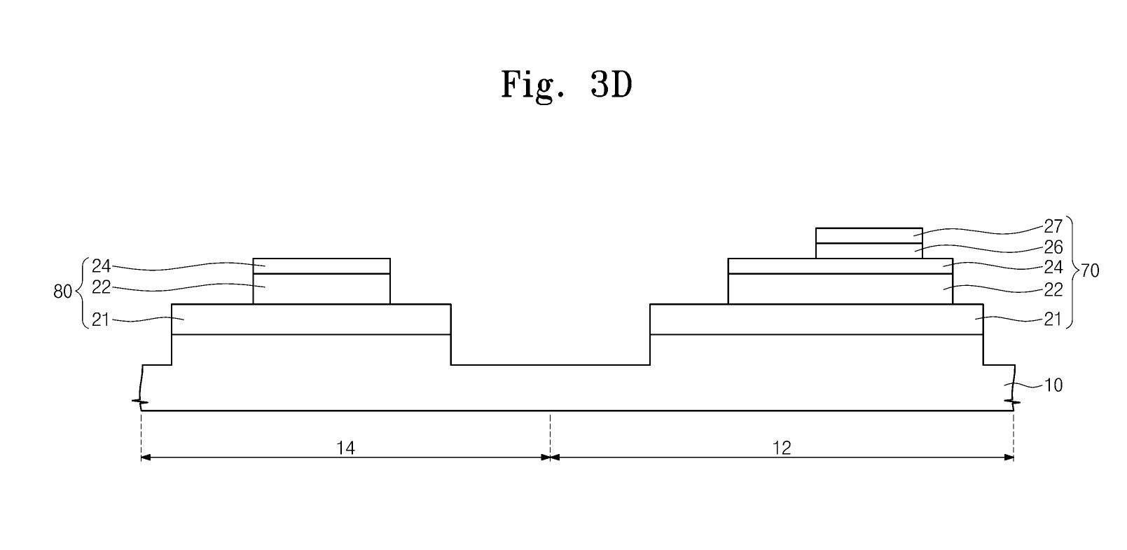

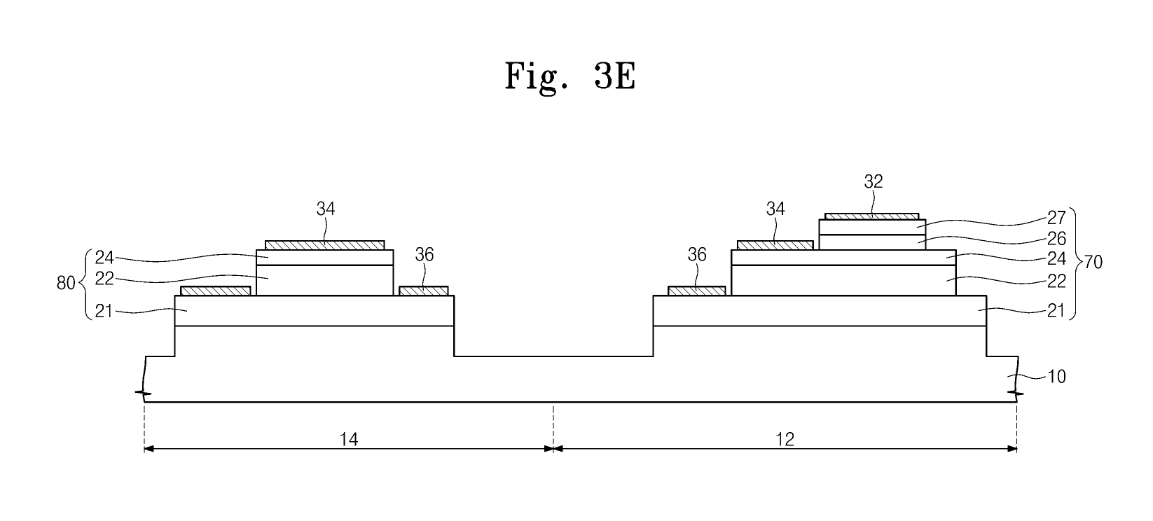

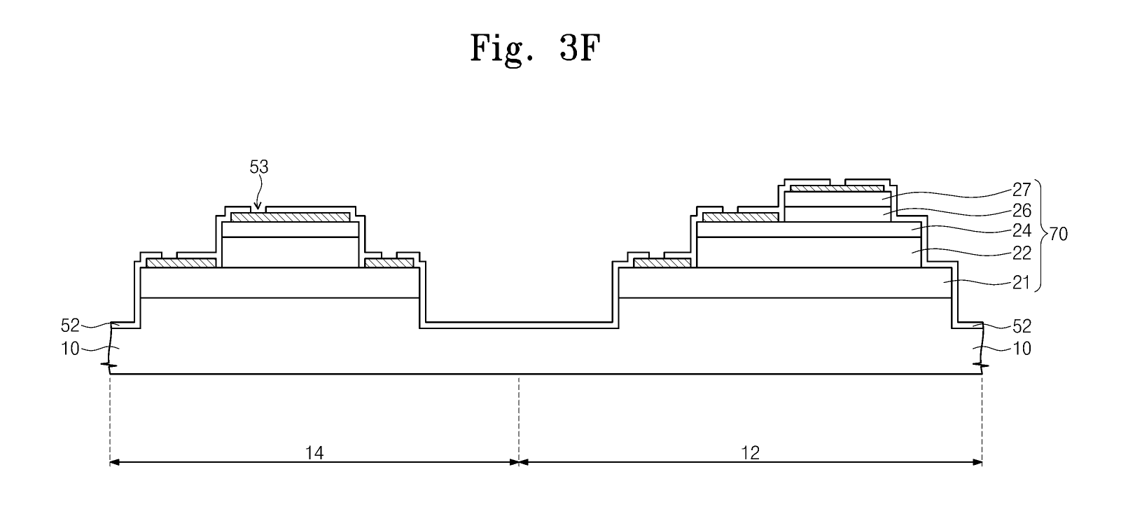

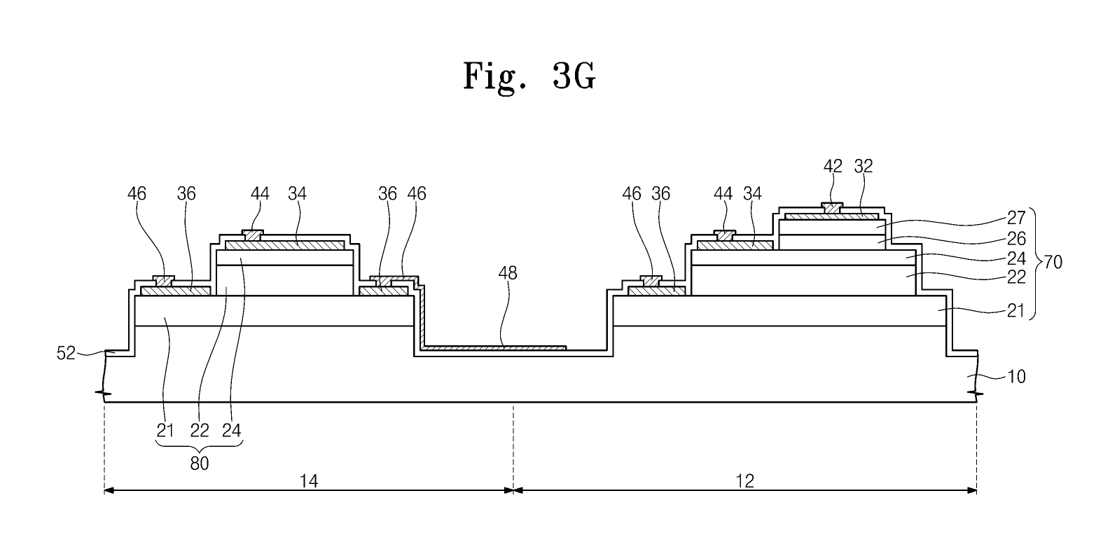

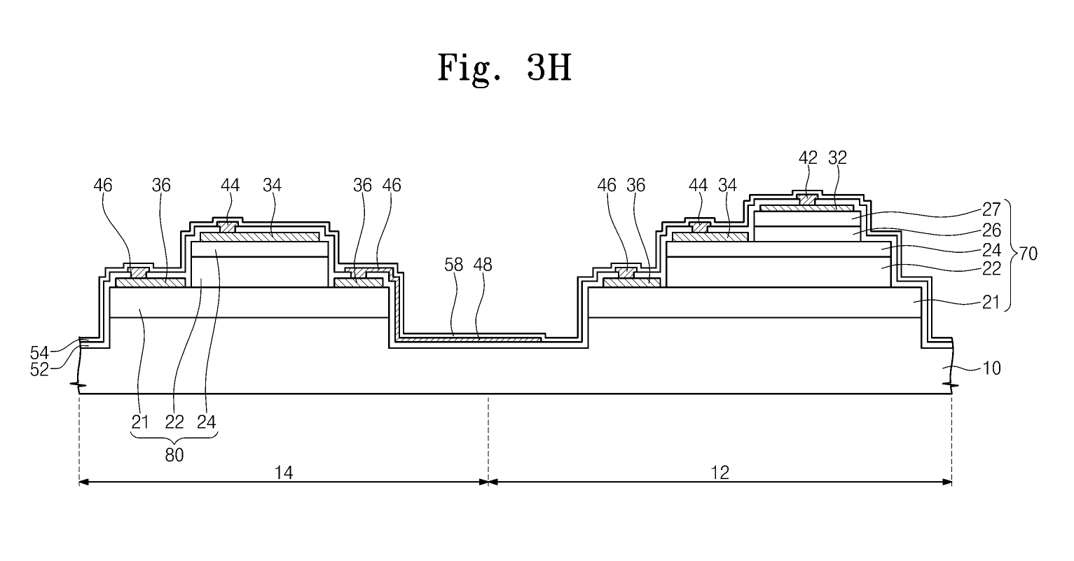

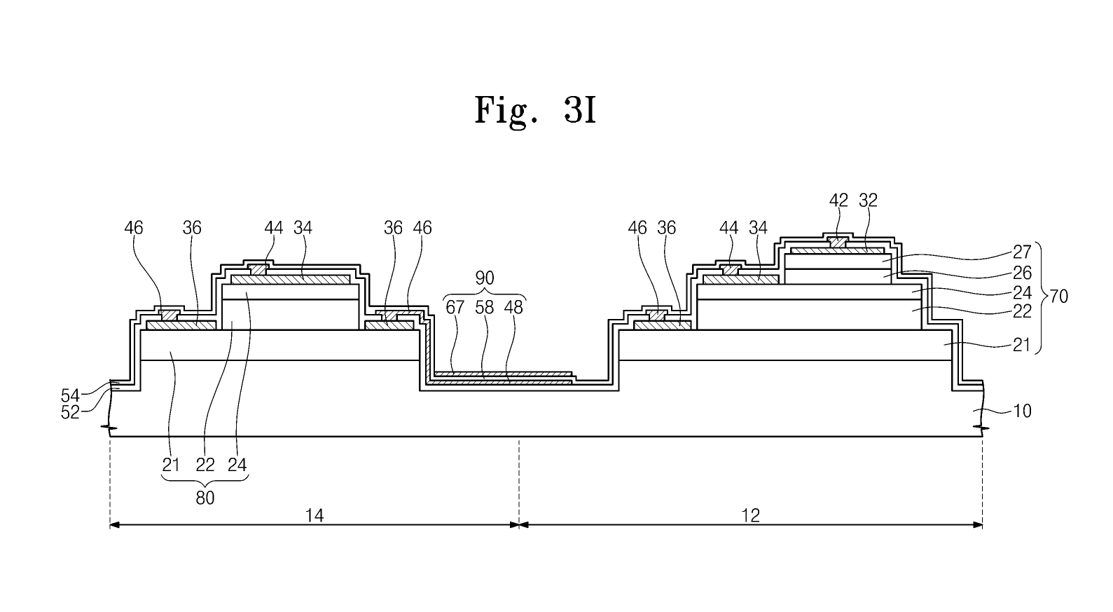

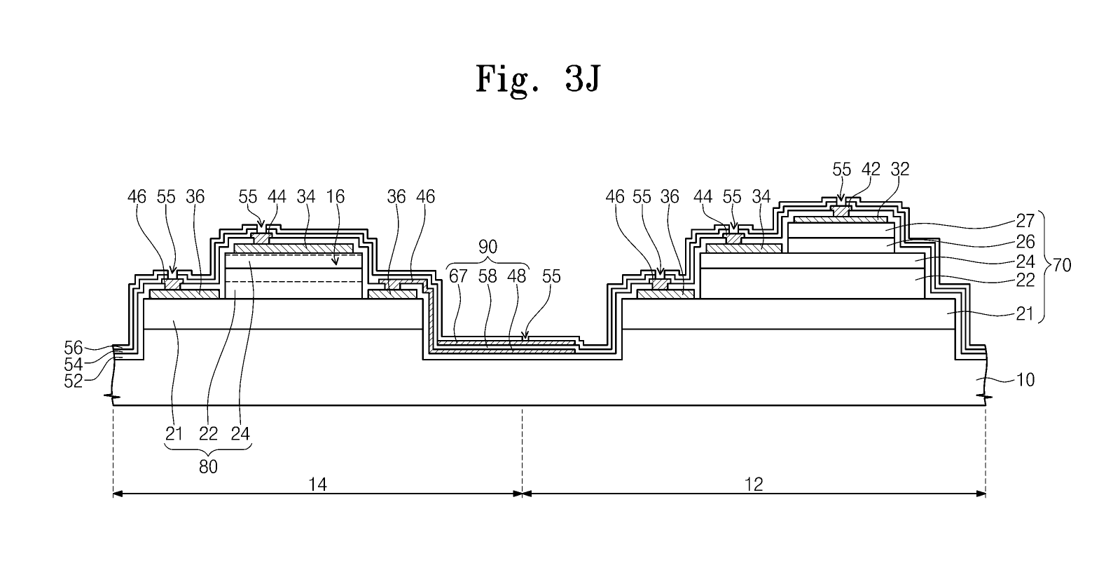

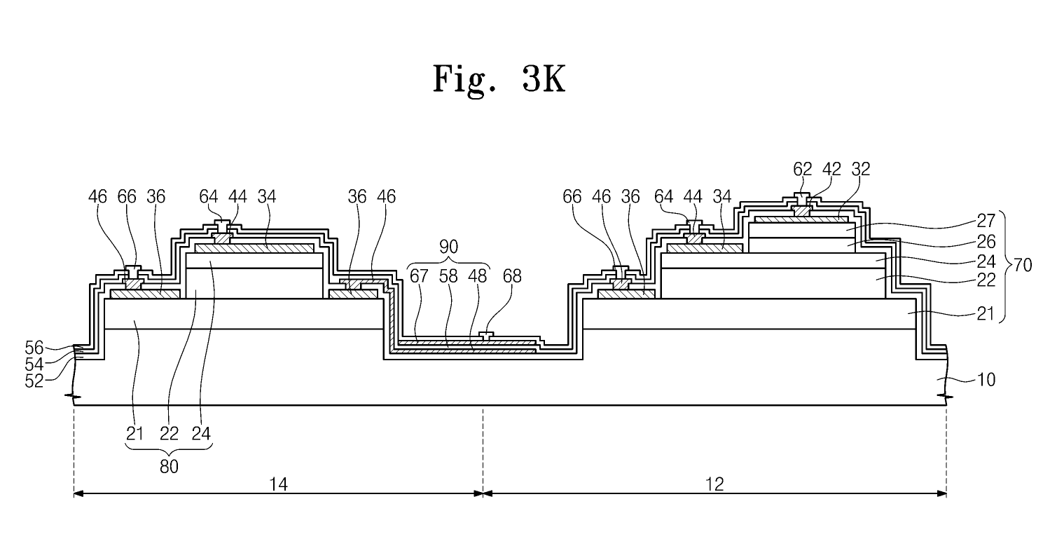

FIGS. 3A through 3K are sectional views illustrating a method of manufacturing a semiconductor device according to an embodiment of the present invention.

Referring to FIG. 3A, a sub collector layer 21, a collector layer 22, a base layer 24, an emitter layer 26, and an emitter cap layer 27 may be sequentially stacked on a substrate 10. The sub collector layer 21, the collector layer 22, the base layer 24, the emitter layer 26, and the emitter cap layer 27 may include a hetero junction compound semiconductor such as GaAs. The compound semiconductor may be formed through a Metal Organic Chemical Vapor Deposition (MOCVD) method.

Referring to FIG. 3B, the emitter layer 26 and the emitter cap layer 27 are partially removed in the first region 12 of the substrate 10, and the emitter layer 26 and the emitter cap layer 27 are removed in the second region 14 to expose the base layer 24. The emitter layer 26 and the emitter cap layer 27 may be patterned through a photolithography process.

Referring to FIGS. 1A, 1B, and 3C, the base layer 24 and the collector layer 22 of the first and second regions 12 and 14 are partially removed to expose the sub collector layer 21. The base layer 24 and the collector layer 22 may be patterned through a photolithography process. The emitter layer 26, the base layer 24, and the collector layer 22 of the first region 12 may be a bipolar transistor 70. The base layer 24 and the collector layer 22 of the second region 14 may be a variable capacitance diode 70. The variable capacitance diode 70 may change electric capacitance according to the first and second depletion regions 16 and 18 induced between the base layer 24 and the collector layer 22.

Accordingly, since the viable capacitance diode 80 and the bipolar transistor 70 are simultaneously formed, the method of manufacturing a semiconductor device according to embodiments of the present invention may improve or maximize productivity.

Referring to FIG. 3D, the sub collector 21 and the substrate 10 between the first and second regions 12 and 14 are partially removed to separate the bipolar transistor 70 from the variable capacitance diode 80. The sub collector layer 21 between the first and second regions 12 and 14 may be removed through a photolithography process.

Referring to FIG. 3E, first to third contract pads 32, 34, and 36 may be formed on the bipolar transistor 70 of the first region 12 and second and third contact pads 34 and 36 may be formed on the variable capacitance diode 80 of the second region 14. The first to third contact pads 32, 34, and 36 may include metals such as gold, silver, aluminum, copper, tungsten, molybdenum, or zinc, which ohmic-contact a compound semiconductor. The first to third contact pads 32, 34, and 36 may be patterned through a photolithography process. The photolithography process may include a photoresist pattern (not shown) forming process exposing a portion on the sub collector layer 21, a metal deposition process depositing metal on the front of the substrate 10, and a lift off process removing metal on the photoresist pattern.

Referring to FIG. 3F, a first insulation layer 52 covering the front of the substrate 10 may be formed. First contact holes 53 may be formed by removing the first insulation layer 52 on the first to third contact pads 32, 34, and 36 in the first and second regions 12 and 14. The first insulation layer 52 may cover the front of the substrate 10 including the bipolar transistor 70 and the variable capacitance diode 80. The first insulation layer may include at least one of a silicon oxide layer, a silicon nitride layer, and a silicon oxide nitride layer. The first contact holes 53 may be patterned through a photolithography process. The photolithography process may include a photoresist pattern (not shown) forming process exposing a portion of the first insulation layer 52 on the first to third contact pads 32, 34, and 36 and an etching process etching the first insulation layer 52 exposed by the photoresist pattern. The photoresist pattern may be removed through a cleansing process.

Referring to FIG. 3G, first to third electrode 42, 44, and 46 may be formed on the first to third contact pads 32, 34, and 36. The first to third electrode 42, 44, and 46 may include metals such as gold, silver, aluminum, copper, tungsten, molybdenum, or zinc. The third electrode 46 on the variable capacitance diode 80 may include a lower electrode 48 extending from the second region 14 to the first region 12. The lower electrode 48 may be disposed in the first and second regions 12 and 14 of the substrate 10. The lower electrode 48 may be insulated from the substrate 10 by the first insulation layer 52.

Referring to FIG. 3H, a second insulation layer 54 may be formed on the first to third electrodes 42, 44, and 46. The second insulation layer 54 may include at least one of a silicon oxide layer, a silicon nitride layer, and a silicon oxide nitride layer. The second insulation layer 54 ma include a dielectric layer 58 on the lower electrode 48.

Referring to FIG. 3I, an upper electrode 67 may be formed on the dielectric layer 58 facing the lower electrode 48. The upper electrode 67 may include metals such as gold, silver, aluminum, copper, tungsten, molybdenum, or zinc. The upper electrode 67 may be patterned through a photolithography process. The photolithography process includes a photoresist pattern forming process exposing the dielectric layer 58 on the lower electrode 48, a metal deposition process depositing metal on the photoresist pattern, and a lift off process removing metal on the photoresist pattern.

Referring to FIG. 3J, a third insulation layer 56 may be formed on the front of the surface 10 including the upper electrode 67. Second contact holes 55 may be formed by removing the second and third insulation layers 54 and 56 on the first to third electrodes 42, 44, and 46.

Referring to FIG. 3K, first to third interconnections 62, 64, and 66 may be formed on the first to third electrodes 42, 44, and 46 and a fourth interconnection 68 may be formed on the upper electrode 67. The first to third interconnections 62, 64, and 66 may include metals such as gold, silver, aluminum, copper, tungsten, molybdenum, or zinc. The first to third interconnections 62, 64, and 66 may be patterned through a photolithography process.

Accordingly, since the viable capacitance diode 80 and the bipolar transistor 70 are simultaneously formed, the method of manufacturing a semiconductor device according to embodiments of the present invention may improve or maximize productivity.

As mentioned above, according to embodiments of the present invention, since a bipolar transistor and a variable capacitance diode are integrated into one substrate so that a chip size may be minimized Additionally, the variable capacitance diode and the bipolar transistors are simultaneously formed during manufacturing processes. Thus, a method of manufacturing a semiconductor device according to embodiments of the present invention may increase or maximize productivity.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A semiconductor device comprising:
a substrate including a first region and a second region;
a transistor including first to third conductive impurity layers stacked on the substrate of the first region; and
a variable capacitance diode spaced apart from the transistor of the first region and including the first and second conductive impurity layers stacked on the substrate of the second region.

2. The semiconductor device of claim 1, wherein the first to third conductive impurity layers comprise a collector layer, a base layer, and an emitter layer, respectively.

3. The semiconductor device of claim 2, wherein the variable capacitance diode comprises a sub collector layer between the first conductive impurity layer and the substrate.

4. The semiconductor device of claim 3, wherein the transistor comprises a first electrode on the emitter layer, a second electrode on the base layer, and a third electrode on the sub collector layer; and
the variable capacitance capacitor comprises a fourth electrode on the base layer and a plurality of fifth electrodes on the sub collector layer.

5. The semiconductor device of claim 4, further comprising a fixed capacitance capacitor having:
a lower electrode extending from at least one of the plurality of fifth electrodes on the substrate in the second region and around a boundary of the second region;
an insulation layer on the lower electrode; and
an upper electrode on the insulation layer facing the lower electrode.

6. A method of manufacturing a semiconductor device, the method comprising:
stacking first to third conductive impurity layers on a front of a substrate including first and second regions;
exposing the second conductive impurity layer by removing the third conductive impurity layer on the first region and partially removing the third conductive impurity layer on the second region; and
forming a transistor including the first to third conductive impurity layers on the first region and a variable capacitance diode including the first and second conductive impurity layers on the second region by partially removing the second and third conductive impurity layers on the first and second regions, respectively.

7. The method of claim 6, further comprising forming a sub conductive impurity layer having the same conductive type as the first conductive impurity layer between the first conductive impurity layer and the substrate.

8. The method of claim 7, wherein the sub conductive impurity layer is exposed when the second and third conductive impurities are removed.

9. The method of claim 8, further comprising separating the variable capacitance diode from the transistor by removing a portion of the substrate between the first and second regions and the sub conductive impurity.

10. The method of claim 9, further comprising forming first to third contact pads on the first to third conductive impurity layers in the first and second regions.

11. The method of claim 10, further comprising:
forming a first insulation layer on a front of the substrate including the first to third contact pads; and
forming first contact holes by partially removing the first insulation layer on the first and third contact pads.

12. The method of claim 11, further comprising forming first to third electrodes connected to the first to third contact pads in the first contact holes.

13. The method of claim 12, wherein at least one of the third electrodes on the second region comprises a lower electrode extended between the first region and the second region.

14. The method of claim 13, further comprising:
forming a second insulation layer on the front of the substrate on the lower electrode; and
forming an upper electrode on the second insulation layer facing the lower electrode.

15. The method of claim 14, further comprising:
forming a third insulation layer on the front of the substrate including the upper electrode;
forming second contact holes by removing the second insulation layer and the third insulation layer on the first to third electrodes and the third insulation layer on the upper electrode; and
forming first to fourth interconnections connected to the first to third electrodes and the upper electrode in the second contact holes.
